(19) United States
(12) Patent Application Publication
(10) Pub. No.: US 2021/0072327 A1
(43) Pub. Date: Mar. 11, 2021

(54) MAGNETIC FLUX CONCENTRATOR FOR OUT-OF-PLANE DIRECTION MAGNETIC FIELD CONCENTRATION

(71) Applicant: TEXAS INSTRUMENTS INCORPORATED, Dallas, TX (US)

(72) Inventors: Jo BITO, Dallas, TX (US); Benjamin Stassen COOK, Addison, TX (US); Dok Won LEE, Mountain View, CA (US); Keith Ryan GREEN, Prosper, TX (US); Kenji OTAKE, Nagano (JP)

(21) Appl. No.: 16/565,130

(22) Filed: Sep. 9, 2019

(51) Int. Cl. G01R 33/00; G01R 33/07

(52) U.S. Cl. CPC G01R 33/0011; G01R 33/07

(57) ABSTRACT

A structure includes a substrate which includes a surface. The structure also includes a horizontal-type Hall sensor positioned within the substrate and below the surface of the substrate. The structure further includes a protective overcoat layer positioned above the surface of the substrate, and a sphere-shaped magnetic concentrator positioned above the protective overcoat layer. Instead of or in addition to the sphere-shaped magnetic concentrator, the structure may include an embedded magnetic concentrator positioned within the substrate and below the horizontal-type Hall sensor.

### BACKGROUND

A two-dimensional (2D) speed and direction sensor employs both horizontal and vertical Hall sensors. A Hall sensor is used to measure the magnitude of a magnetic field. Its output voltage is directly proportional to the magnetic field strength through it. Hall sensors may be used for proximity sensing, positioning, speed detection, and current sensing applications. A 2D pulse encoder also employs horizontal Hall sensors, but with a sensitivity enhancing magnetic concentrator formed via package level deposition, such as via pick-and-place of a magnetic concentrator disk. Since the magnetic concentrator is disk-shaped, a magnetic field intensity near the Hall sensor is weak resulting in low structure sensitivity.

### SUMMARY

In at least one example, a structure includes a substrate including a surface. The structure also includes a horizontal-type Hall sensor positioned within the substrate and below the surface of the substrate. The structure further includes a protective overcoat layer positioned above the surface of the substrate, and a sphere-shaped magnetic concentrator positioned above the protective overcoat layer.

In another example, a structure includes a substrate including a surface. The structure also includes a horizontal-type Hall sensor positioned within the substrate and below the surface of the substrate. The structure further includes an embedded magnetic concentrator positioned within the substrate and below the horizontal-type Hall sensor.

In yet another example, a method of forming a structure includes forming a substrate including a surface, positioning a horizontal-type Hall sensor within the substrate and below the surface of the substrate, forming a protective overcoat layer above the surface of the substrate, and placing a sphere-shaped magnetic concentrator above the protective overcoat layer.

In yet another example, a method of forming a structure includes forming a substrate including a surface, positioning a horizontal-type Hall sensor within the substrate and below the surface of the substrate, and forming an embedded magnetic concentrator within the substrate and below the horizontal-type Hall sensor.

### BRIEF DESCRIPTION OF THE DRAWINGS

For a detailed description of various examples, reference will now be made to the accompanying drawings in which:

FIG. 1 is a cross-sectional schematic side view of a structure including a substrate, horizontal-type Hall sensor, inter-level dielectric oxide layer, protective overcoat layer, embedded magnetic concentrator, and sphere-shaped magnetic concentrator.

FIG. 2 is a cross-sectional schematic side view of a structure including a substrate, horizontal-type Hall sensor, inter-level dielectric oxide layer, protective overcoat layer, embedded magnetic concentrator, patterned magnetic concentrators.

FIG. 3 is a perspective top-side view of a structure including a sphere-shaped magnetic concentrator positioned above the protective overcoat layer.

FIG. 4 is a perspective bottom-side view of a structure including a cylinder or rod-shaped embedded magnetic concentrator positioned within the substrate and below (with respect to the orientation in FIG. 1) the horizontal-type Hall sensor.

FIG. 5 is a perspective bottom-side view of a structure including a pyramid-shaped embedded magnetic concentrator positioned within the substrate. With respect to the orientation in FIG. 1 (i.e., by replacing the rod-shaped embedded magnetic concentrator shown in FIG. 1 with a pyramid-shaped embedded magnetic concentrator), the pyramid-shaped embedded magnetic concentrator is positioned below the horizontal-type Hall sensor.

FIG. 6 is a perspective bottom-side view of a structure including a cylindrical cone-shaped embedded magnetic concentrator positioned within the substrate. With respect to the orientation in FIG. 1 (i.e., by replacing the rod-shaped embedded magnetic concentrator shown in FIG. 1 with a cylindrical cone-shaped embedded magnetic concentrator), the cylindrical cone-shaped embedded magnetic concentrator is positioned below the horizontal-type Hall sensor.

FIG. 7 is a perspective top-side view of a structure including a patterned magnetic concentrator positioned below the protective overcoat layer. The protective overcoat layer is not shown.

FIG. 8 is a perspective schematic top-side view of a structure including an array of sphere-shaped magnetic concentrators positioned above the protective overcoat layer.

FIG. 9 is a perspective schematic top-side view of a structure including an array of rod-shaped embedded magnetic concentrators positioned within the substrate.

FIG. 10A is a perspective schematic top-side view of a structure including an array of rod-shaped embedded magnetic concentrators positioned within the substrate, and a patterned magnetic concentrator positioned above the array of rod-shaped embedded magnetic concentrators.

FIG. 10B is a schematic top view of the structure shown in FIG. 10A.

### DETAILED DESCRIPTION

An aspect of this description is to increase the sensitivity of a Hall sensor with a combination of a magnetic concentrator and at least one horizontal Hall sensor. A Hall sensor is a device that is used to measure the magnitude of a magnetic field. Its output voltage is directly proportional to the magnetic field strength through it. Hall sensors are used for proximity sensing, positioning, speed detection, direction detection, rotation detection, and current sensing applications. Hall sensors may be employed in a magnetic switch or in a rotational switch or shifter, where a Hall sensor measures the change in direction or rotation of the switch or shifter.

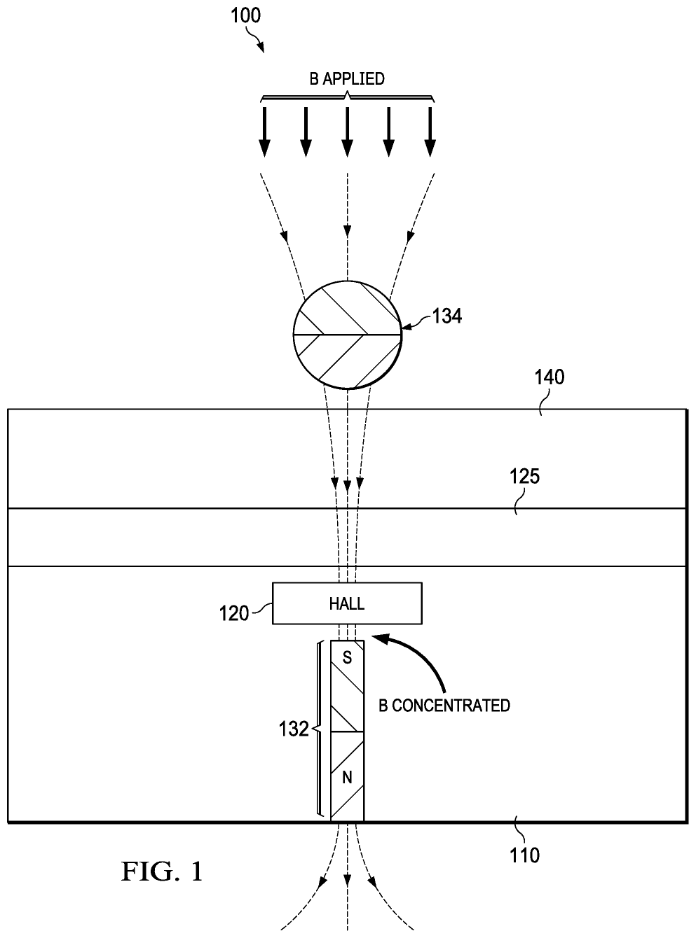

A horizontal Hall sensor has a longitudinal axis that is horizontal and parallel with respect to a substrate's flat upper surface also extending in the horizontal direction. Likewise, a vertical Hall sensor has a longitudinal axis that is vertical and perpendicular with respect to a substrate's flat upper horizontal surface. A horizontal Hall sensor measures the vertical magnetic field, and conversely, a vertical Hall sensor measures the horizontal magnetic field. The use of the terms “horizontal” and “vertical” is not to be interpreted as being limited with reference to only the ground. It is to be interpreted with respect to the elements of the structure. For example, the structure in FIG. 1 may be rotated, for example, 90°. With this rotation, the horizontal Hall sensor 120 would still be considered a “horizontal Hall sensor” and would still measure the vertical magnetic field. Other terms such as “top”, “bottom”, “above”, and “below” should be similarly interpreted.

In an example, FIG. 1 shows a cross-sectional schematic side view of a structure 100 including a substrate 110, horizontal-type Hall sensor 120, inter-level dielectric oxide layer 125, embedded magnetic concentrator 132, protective overcoat layer 140, and sphere-shaped magnetic concentrator 134. As illustrated in FIG. 1, a magnetic field is applied out-of-plane (i.e., in a vertical direction). The substrate 110 may include Si, glass, ceramic, etc. Below the surface of the substrate 110 is a horizontal-type Hall sensor 120. The horizontal-type Hall sensor 120 is electrically connected to a circuit (not shown) so that the Hall sensor 120 can measure the magnetic field. The circuitry may be integrated on the substrate 110, e.g., within the inter-level dielectric oxide layer 125. The inter-level dielectric oxide layer 125 contains the metal routing for the Hall sensor and associated integrated circuit(s). Alternatively, the circuitry may be positioned at a distant location (e.g., on another substrate). Although FIG. 1 illustrates both embedded magnetic concentrator 132 and sphere-shaped magnetic concentrator 134 being employed, either magnetic concentrator may solely be employed. When both magnetic concentrators are employed, the concentration effect of the magnetic field is further amplified/enhanced than if only one of the magnetic concentrators were employed.

During the wafer processing, before the protective overcoat layer 140 is formed, the embedded magnetic concentrator 132 is formed by, for example, an etching process (such as through-silicon via (TSV)) through the bottom surface of substrate 110 whereby a via or hole is formed, followed by a deposition process to fill the etched/via region, such as by sputtering or spraying of a ferromagnetic material (e.g., NiFe). The fill material (i.e., resultant embedded magnetic concentrator 132 material) is mentioned below.

The embedded magnetic concentrator 132 is rod-shaped and includes ferromagnetic material such as NiFe (e.g., in a horizontal thickness (diameter) of 10 μm-100 μm and a vertical height of 60 μm-800 μm). The top surface of the embedded magnetic concentrator 132 is spaced below the Hall sensor 120 a distance in the range of 10 μm-100 μm, while the bottom surface of the embedded magnetic concentrator 132 extends to the bottom surface of the substrate 110.

By positioning the embedded magnetic concentrator 132 below the Hall sensor 120, a magnetic field applied substantially vertically from above the Hall sensor 120 will impinge the surface of the Hall sensor 120 vertically and be concentrated at the Hall sensor 120, thereby providing amplification/enhancement of the magnetic field prior to reaching the Hall sensor 120. The Hall sensor 120 receives the amplified magnetic field. In other words, having the embedded magnetic concentrator 132 below the Hall sensor 120 keeps the magnetic field concentrated when the magnetic field exits the bottom of the Hall sensor 120 and before the magnetic field exits the bottom surface of the substrate 110.

In an example, the sphere-shaped magnetic concentrator 134 may be included in structure 100 of FIG. 1. The sphere-shaped magnetic concentrator 134 may be formed by pick-and-place or other deposition process. The sphere-shaped magnetic concentrator 134 includes ferromagnetic material such as NiFe and is formed with a diameter within a range of 30 μm-450 μm. The bottom surface of the sphere-shaped magnetic concentrator 134 is spaced above the horizontal-type Hall sensor 120 a distance in the range of 4 μm-50 μm.

The sphere-shaped magnetic concentrator 134 is placed above the protective overcoat layer 140 and optionally within a layer of, for example, polyamide (which may be 10-30 um thick). The polyamide layer (not shown), if employed, is formed over the protective overcoat layer 140. The sphere-shaped magnetic concentrator 134 may be formed within or, alternatively, may be formed above the polyamide layer. Polyamide has good mechanical elongation and tensile strength which helps in adhesion, temperature stability, and helps with mechanical stability of the die, resulting in the die being less susceptible to changes in pressure/stresses from mold compounds.

By positioning the sphere-shaped magnetic concentrator 134 above the Hall sensor 120 and by virtue of the spherical shape, a magnetic field applied substantially vertically from above the sphere-shaped magnetic concentrator 134 will impinge the surface of the Hall sensor 120 vertically and be concentrated at the Hall sensor 120, thereby providing amplification/enhancement of the magnetic field prior to reaching the Hall sensor 120. The Hall sensor 120 receives the amplified magnetic field.

In one implementation, the protective overcoat layer 140 is a layer of SiON or other dielectric material (e.g., in a thickness of 2.8 μm), though other thicknesses can alternatively be used.

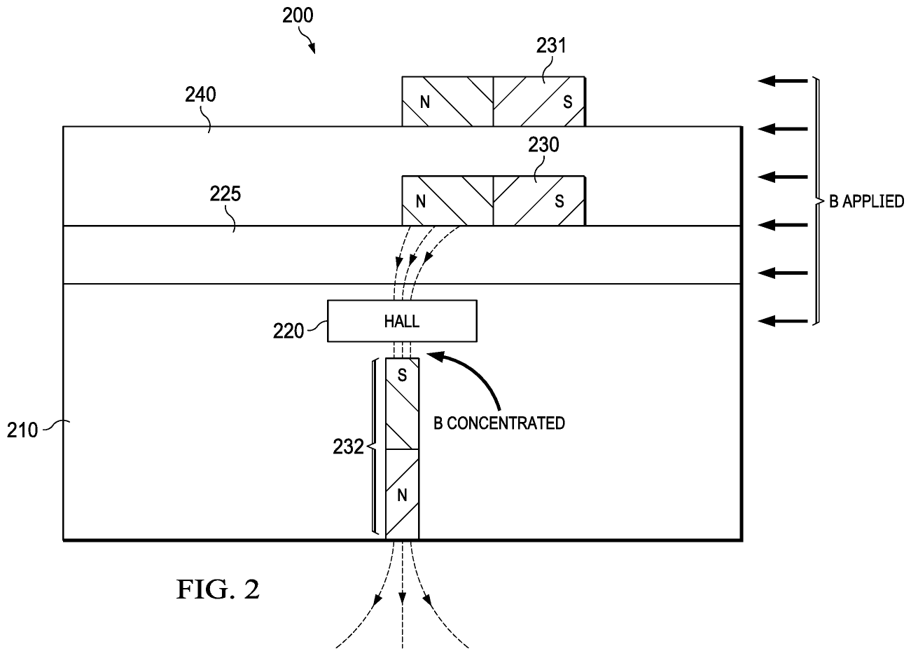

In an example, FIG. 2 shows a cross-sectional schematic side view of a structure 200 including a substrate 210, horizontal-type Hall sensor 220, inter-level dielectric oxide layer 225, protective overcoat layer 240, and patterned magnetic concentrators 230, 231. As illustrated in FIG. 2, a magnetic field is applied in-plane (i.e., in a horizontal direction). The embedded magnetic concentrator 232 may be the same as the embedded magnetic concentrator 132 employed in FIG. 1. In addition to the embedded magnetic concentrator 232, either or both of patterned magnetic concentrators 230, 231 may be employed.

The patterned magnetic concentrator 230 (i.e., formed below the protective overcoat layer 240) may be of the type (e.g., size, shape, and/or including multilayers of magnetic material) disclosed in co-pending application Ser. No. 16/521,053 (the '053 application), filed Jul. 24, 2019. The layers adjacent to magnetic concentrator in the '053 application may also be similarly employed in this example. The patterned magnetic concentrator 230 may be formed using any of the processes described for forming the magnetic concentrator in the '053 application. Additional horizontal Hall sensors may be placed below the patterned magnetic concentrator 230 (i.e., within the substrate 210) similar to those disclosed in the '053 application.

As an alternative to or in addition to the patterned magnetic concentrator 230, patterned magnetic concentrator 231 may be employed. The patterned magnetic concentrator 231 may be of the type (e.g., size, shape, and/or including multilayers of magnetic material) disclosed in the '053 application, even though the patterned magnetic concentrator 231 is formed above the protective overcoat layer 240. The layers adjacent the magnetic concentrator in the '053 application may also be similarly employed in this example. The patterned magnetic concentrator 231 may be formed using any of the processes described for forming the magnetic concentrator in the '053 application. Additional horizontal Hall sensors may be placed below the patterned magnetic concentrator 231 (i.e., within the substrate 210) similar to those disclosed in the '053 application.

The input magnetic field is redirected or converted from horizontal to vertical as a result of employing one or both of the patterned magnetic concentrators 230, 231, as is also disclosed in the '053 application.

When the combination of the embedded magnetic concentrator 232 and either or both of patterned magnetic concentrators 230, 231 are employed, the concentration effect of the magnetic field is further amplified/enhanced before reaching the Hall sensor than if any one of the magnetic concentrators were employed.

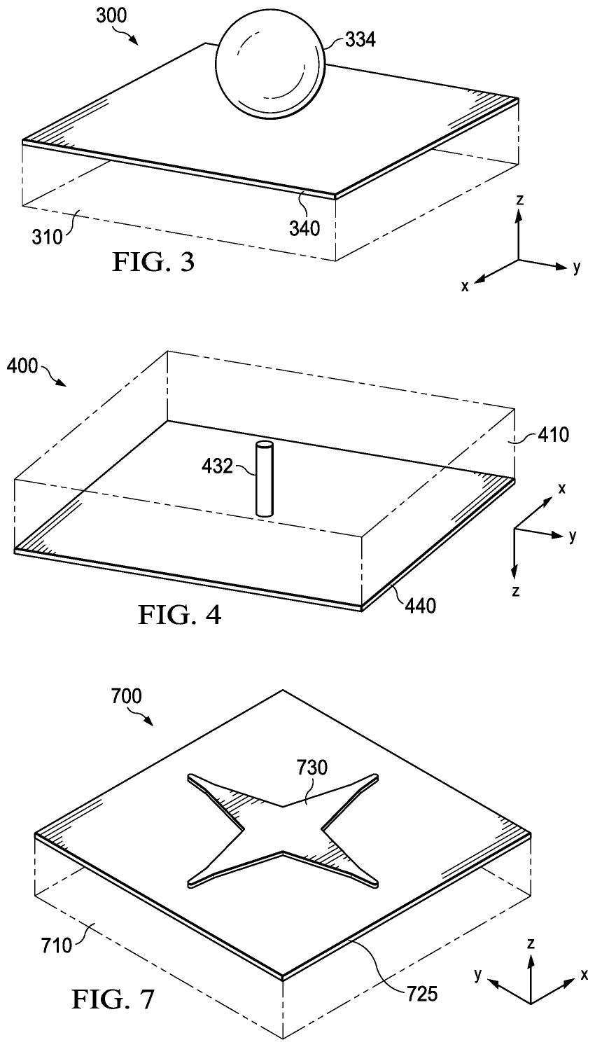

In an example, FIG. 3 shows a perspective top-side view of a structure 300 including a substrate 310 and a sphere-shaped magnetic concentrator 334 positioned above the protective overcoat layer 340. For simplicity purposes, the horizontal Hall sensor and remaining layers are not shown. The sphere-shaped magnetic concentrator 334 may have a diameter of, for example, in the range of 30 μm-450 μm. The substrate 310 may have a width in the range of 0.7 mm-2 mm and a depth/thickness in the range of 60-800 μm. The Hall sensor may have a thickness (i.e., depth of the Hall well) in the range of 1-3 μm and may be spaced a distance of 3-5 μm from the substrate 310 top surface. The protective overcoat layer (not shown) may have any thickness.

In an example, FIG. 4 shows a perspective bottom-side view of a structure 400 including a rod-shaped embedded magnetic concentrator 432 positioned within the substrate 410 and below (with respect to the orientation in FIG. 1) the horizontal-type Hall sensor. The protective overcoat layer 440 is shown. For simplicity purposes, the horizontal Hall sensor and remaining layers are not shown.

In an example, FIG. 5 shows a perspective bottom-side view of a structure 500 including a pyramid-shaped embedded magnetic concentrator 532 positioned within the substrate 510. With respect to the orientation in FIG. 1 (i.e., by replacing the rod-shaped embedded magnetic concentrator shown in FIG. 1 with a pyramid-shaped embedded magnetic concentrator), the pyramid-shaped embedded magnetic concentrator 532 is positioned below the horizontal-type Hall sensor (not shown). The protective overcoat layer 540 is shown. For simplicity purposes, the horizontal Hall sensor and remaining layers are not shown. The pyramid-shaped embedded magnetic concentrator 532 may be hollow or may be filled. In either scenario, the pyramid-shaped embedded magnetic concentrator 532 and/or its filling includes ferromagnetic material such as NiFe. The pyramid-shaped embedded magnetic concentrator 532 may have a horizontal width of 10 μm-100 μm and a vertical height of 60 μm-800 μm. The apex of the pyramid-shaped embedded magnetic concentrator 532 is spaced below the Hall sensor a distance in the range of 10 μm-100 μm, while the bottom surface (i.e., base) of the pyramid-shaped embedded magnetic concentrator 532 extends to the bottom surface of the substrate 510. The pyramid-shaped embedded magnetic concentrator 532 is formed (by, for example, wet etching) within the substrate 510. The above dimensions and spacing associated with the pyramid-shaped embedded magnetic concentrator 532 may be restricted by the angle of the etch: e.g., 54.7 degrees for (100) and (111) face wafer.

In an example, FIG. 6 shows a perspective bottom-side view of a structure 600 including a cylindrical cone-shaped embedded magnetic concentrator 632 positioned within the substrate 610. With respect to the orientation in FIG. 1 (i.e., by replacing the rod-shaped embedded magnetic concentrator shown in FIG. 1 with a cylindrical cone—shaped embedded magnetic concentrator), the cylindrical cone-shaped embedded magnetic concentrator 632 is positioned below the horizontal-type Hall sensor (not shown). The protective overcoat layer 640 is shown. For simplicity purposes, the horizontal Hall sensor and remaining layers are not shown. The cylindrical cone-shaped embedded magnetic concentrator 632 may be hollow or may be filled. In either scenario, the cylindrical cone-shaped embedded magnetic concentrator 632 and/or its filling includes ferromagnetic material such as NiFe. The cylindrical cone-shaped embedded magnetic concentrator 632 may have a horizontal diameter of 10 μm-100 μm and a vertical height of 60 μm-800 μm. The apex of the cylindrical cone-shaped embedded magnetic concentrator 632 is spaced below the Hall sensor a distance in the range of 10 μm-100 μm, while the bottom surface of the cylindrical cone-shaped embedded magnetic concentrator 632 extends to the bottom surface of the substrate 610. The cylindrical cone-shaped embedded magnetic concentrator 632 may be formed in a similar manner to the pyramid-shaped embedded magnetic concentrator 532 described above. The above dimensions and spacing associated with the cylindrical cone-shaped embedded magnetic concentrator 632 may be restricted by the angle of the etch: e.g., 54.7 degrees for (100) and (111) face wafer.

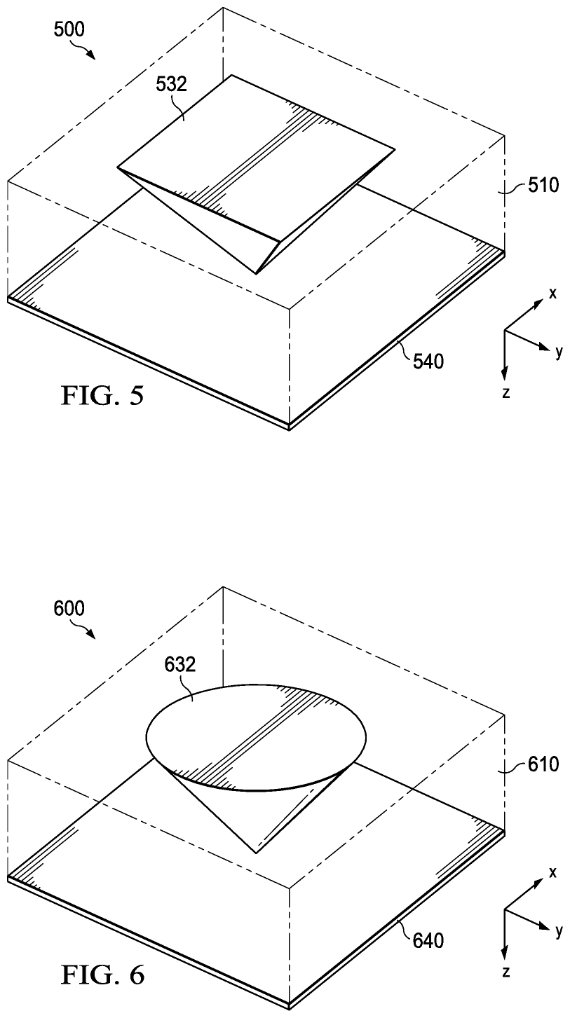

In an example, FIG. 7 shows a perspective top-side view of a structure 700 including a patterned magnetic concentrator 730 positioned below the protective overcoat layer (not shown). The substrate 710 and inter-level dielectric oxide layer 725 are shown. For simplicity purposes, the horizontal Hall sensor(s) and remaining layers are not shown. In this example, additional horizontal Hall sensors may be placed below the patterned magnetic concentrator 730 (i.e., within the substrate 710) similar to those disclosed in the '053 application.

The various patterned shapes and locations of the magnetic concentrator enable a higher structure sensitivity by enhancing/amplifying the magnetic field near the area of the Hall sensors. Different magnetic concentrator shapes enhance the magnetic field by providing different magnetic field outputs while concentrating the outputs near the Hall sensors. Table 1 below indicates the magnetic field enhancement/amplification/concentration from a magnetic concentrator of various exemplary shapes in locations described per the embodiments above, resulting from a, for example, 1 mT applied vertical magnetic flux (i.e., out-of-plane, for the sphere, pyramid, and rod-shaped magnetic concentrators), or a 1 mT applied horizontal magnetic flux (i.e., in-plane, for the patterned, pyramid, and rod-shaped magnetic concentrators). For example, when a 1 mT vertical magnetic flux is applied to a sphere-shaped magnetic concentrator (with a diameter of 150 μm), the vertical magnetic field output would be amplified a factor of 2.8X. As shown in Table 1, the pyramid-shaped magnetic concentrator concentrates the field more than the other shaped magnetic concentrators. The apex of the pyramid is adjacent or near the hall sensor from below and concentrates the magnetic field at the apex. Because the apex includes a point at or near the Hall sensor, the highly concentrated magnetic field experienced by the apex is input to the Hall sensor. The flux enhancements listed in Table 1 assumes each associated magnetic concentrator functioning alone. However, when combining magnetic concentrators (e.g., sphere and rod), a cumulative flux enhancement is achieved.

TABLE 1
Magnetic field enhancement/amplification/concentration dependent
on shape and location of magnetic concentrator

| | Magnetic Concentrator Shape | | | |
|---|---|---|---|---|
| | Sphere | Rod | Pyramid | Patterned |
| Reference | FIG. 3 | FIG. 4 | FIG. 5 | FIG. 7 |
| FIG. | | | | |
| Fabrication | Pick and place/ | Deep reactive-ion | Wet etch + | Sputtering or |
| method | ball drop | etching (DRIE) + | sputtering or | plating |
| | | sputtering or | plating | |
| | | plating | | |
| Material | Ferrite | NiFe | NiFe | NiFe |
| | NiFe coating | | | |
| In-plane | ~1X | ~0 | ~0.3X | ~7X (Sputter) |
| magnetic flux | (Bulk) | | | <5X (Plating) |
| enhancement | | | | |
| (expected at | | | | |
| Hall sensor) | | | | |
| Out-of-plane | ~2.8X | ~3.4X (10 μm | ~5.1X (with 10 μm | ~0 |
| magnetic flux | (150 μm diameter | separation from | separation from | |
| enhancement | sphere) | rod end to Hall | pyramid apex to | |
| (expected at | | sensor) | Hall sensor) | |
| Hall sensor) | | ~1.5X (50 μm | ~2.2X (with 50 μm | |
| | | separation from | separation from | |
| | | rod end to Hall | pyramid apex to | |
| | | sensor) | Hall sensor) | |
| Saturation | <300 mT | <100 mT | <10 mT | <10 mT |
| | (Bulk) | | (Sputter) | (Sputter) |
| | | | <100 mT | <100 mT |
| | | | (Plating) | (Plating) |

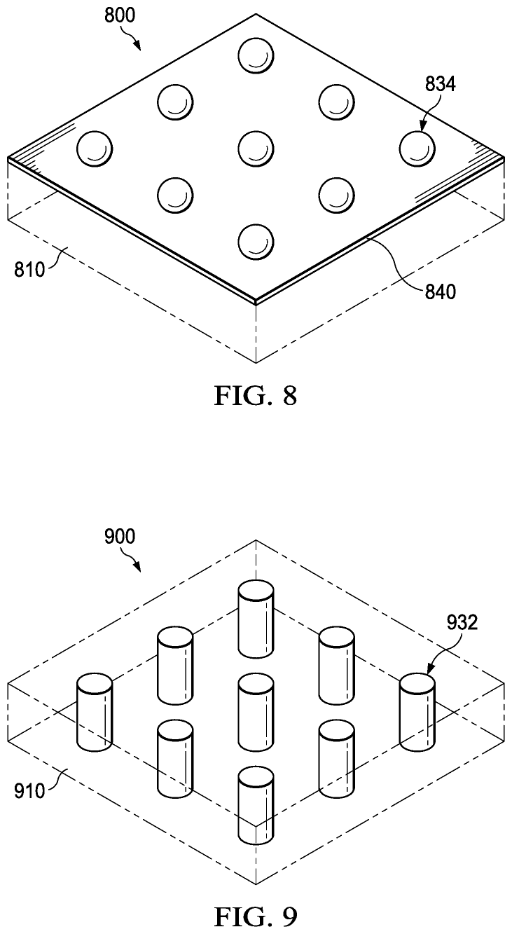

In an example, FIG. 8 shows a perspective schematic top-side view of a structure 800 including a substrate 810 and an array of sphere-shaped magnetic concentrators 834 positioned above the protective overcoat layer 840. For simplicity purposes, the horizontal Hall sensors (positioned below each sphere-shaped magnetic concentrator 834) and remaining layers are not shown.

In an example, FIG. 9 shows a perspective schematic top-side view of a structure 900 including an array of rod-shaped embedded magnetic concentrators 932 positioned within the substrate 910 and below horizontal-type Hall sensors. For simplicity purposes, the horizontal Hall sensors (positioned, respectively, above the rod-shaped embedded magnetic concentrators 932) and remaining layers are not shown.

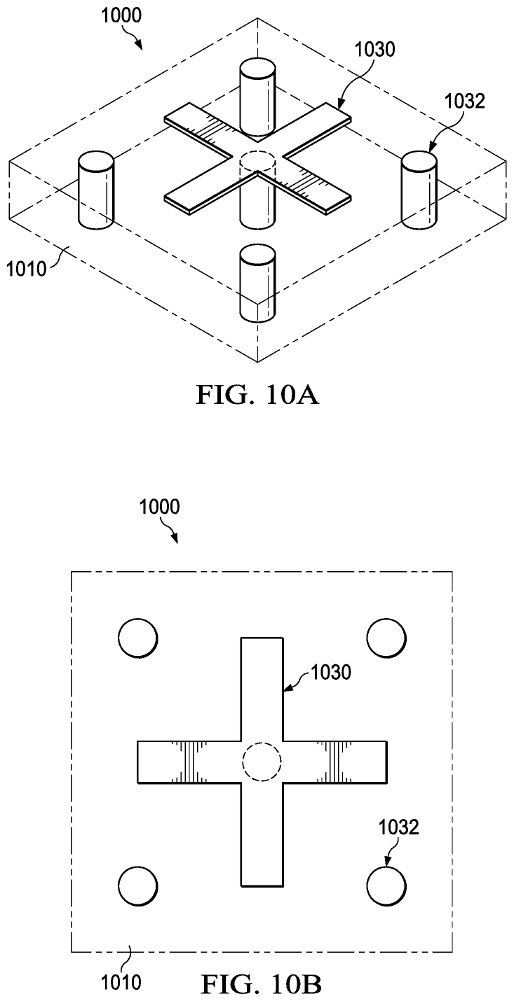

In an example, FIG. 10A shows a perspective schematic top-side view of a structure 1000 including an array of rod-shaped embedded magnetic concentrators 1032 positioned within the substrate 1010 and below horizontal-type Hall sensors, and a patterned magnetic concentrator 1030 positioned above the array of rod-shaped embedded magnetic concentrators 1032. For simplicity purposes, the horizontal Hall sensors (positioned, respectively, above the rod-shaped embedded magnetic concentrators 1032) and remaining layers are not shown. In this example, additional horizontal Hall sensors may be placed below the patterned magnetic concentrator 1030 (i.e., within the substrate 1010) similar to those disclosed in the '053 application. Thus, Hall sensors would be both above the rods and below the tips of the patterned magnetic concentrator 1030. FIG. 10B is a schematic top view of the structure 1000 shown in FIG. 10A. Another exemplary configuration would have the rod-shaped embedded magnetic concentrators 1032 positioned beneath the Hall sensors that are beneath the tips of the patterned magnetic concentrator 1030. Also, with multiple Hall sensors, this configuration is able to detect applied fields in all directions (x,y,z).

With reference again to FIG. 1, when a magnetic field (B) is applied vertically from above, the sphere-shaped magnetic concentrator 134 concentrates the magnetic field. The structures in FIGS. 3-6, 8, and 9 are designed to employ a vertically applied input magnetic field as in FIG. 1. Importantly, with this configuration, a vertical Hall sensor (which measures magnetic field applied horizontally from the side) is not required in the structure.

With reference again to FIG. 2, when a magnetic field (B) is applied horizontally from the side, the patterned magnetic concentrator 230 concentrates the magnetic field. Since the concentration occurs at the tip of the patterned magnetic concentrator 230, the magnetic field will be bent and will generate a horizontal to vertical-direction conversion. With the conversion, the horizontally applied magnetic field (B) will loop and bend into a vertical magnetic field once the magnetic field enters the substrate 210. In other words, an in-plane (x-y) directional input magnetic field is converted to an out-of-plane (z) directional output magnetic field. The patterned magnetic concentrator 231 above the protective overcoat layer 240 functions similarly to the patterned magnetic concentrator 230, i.e., in terms of converting the in-plane (x-y) directional input magnetic field to an out-of-plane (z) directional output magnetic field. The horizontal Hall sensor 220 is positioned within the vertical magnetic fields to maximize its measurement of the magnetic field in the z-direction. The structures in FIGS. 7, 10A, and 10B are designed to employ a horizontally applied input magnetic field as in FIG. 2. Importantly, with this configuration, a vertical Hall sensor (which measures magnetic field applied horizontally from the side) is not required in the structure.

With reference again to FIG. 1 and Table 1 above, an applied magnetic field of 1 mT in the z direction will result in 14 mT maximum output in the z-direction. Up to 6.2X (combination of 2.8X for the sphere and 3.4X for the rod—per Table 1, assuming 10 μm separation from rod end to Hall sensor) sensitivity enhancement/amplification/concentration of the magnetic field may be achieved with this structure.

With reference again to FIG. 2 and Table 1 above, an applied magnetic field of 1 mT in the x direction will result in 14 mT maximum output in the z direction. Up to 10.4X (combination of 7X for the sputtered patterned magnetic concentrator 230 and 3.4X for the rod—per Table 1, assuming 10 μm separation from rod end to Hall sensor) sensitivity enhancement/amplification/concentration of the magnetic field may be achieved with this structure.

Hall sensors are shown in the figures as rectangle-shaped from the top view, but they may be other shapes such as a cross. Also, any of the single Hall sensors may alternatively be replaced with an array (i.e., two or more) of Hall sensors. The arrays (ensembles) are made by cross-connecting two or four sensors with each other in a particular array. The purpose of the arrays is to reduce offset and resistance. Offset negatively impacts sensor accuracy. And resistance introduces thermal noise and sets voltage headroom.

A magnetic concentrator in any of the above examples may be employed alone or in combination with at least one of the magnetic concentrators from another example. The use of additional magnetic concentrators provide additional increase in the magnetic field output.

In any of the above examples, employing only horizontal Hall sensors decreases the degree of possible mismatch between Hall sensors in terms of calibrating, whereas employing both horizontal and vertical Hall sensors require additional or extensive calibrating, thereby adding significant complexity and time for wafer fabrication and packaging.

With reference again to at least FIGS. 1 and 8, in at least one example, a structure includes a substrate including a surface. The structure also includes a horizontal-type Hall sensor positioned within the substrate and below the surface of the substrate. The structure further includes a protective overcoat layer positioned above the surface of the substrate, and a sphere-shaped magnetic concentrator positioned above the protective overcoat layer. The sphere-shaped magnetic concentrator is positioned above the horizontal-type Hall sensor. The structure may further include an array of horizontal-type Hall sensors positioned within the substrate and below the surface of the substrate, and an array of sphere-shaped magnetic concentrators positioned above the protective overcoat layer. The sphere-shaped magnetic concentrators are respectively positioned above the horizontal-type Hall sensors.

In another example, a method of forming a structure includes forming a substrate including a surface, positioning a horizontal-type Hall sensor within the substrate and below the surface of the substrate, forming a protective overcoat layer above the surface of the substrate, and placing a sphere-shaped magnetic concentrator above the protective overcoat layer. The step of placing includes positioning the sphere-shaped magnetic concentrator above the horizontal-type Hall sensor. The method may further include positioning an array of horizontal-type Hall sensors within the substrate and below the surface of the substrate, and placing an array of sphere-shaped magnetic concentrators above the protective overcoat layer. The step of placing the array of sphere-shaped magnetic concentrators above the protective overcoat layer includes respectively positioning the sphere-shaped magnetic concentrators above the horizontal-type Hall sensors.

With reference again to at least FIGS. 1, 2 and 9, in another example, a structure includes a substrate including a surface. The structure also includes a horizontal-type Hall sensor positioned within the substrate and below the surface of the substrate. The structure further includes an embedded magnetic concentrator positioned within the substrate and below the horizontal-type Hall sensor. The embedded magnetic concentrator may include a shape selected from the group consisting of rod, pyramid, cylindrical, and combinations thereof. The structure may further include an array of horizontal-type Hall sensors positioned within the substrate and below the surface of the substrate, and an array of embedded magnetic concentrators positioned within the substrate, wherein the embedded magnetic concentrators are respectively positioned below the horizontal-type Hall sensors.

The structure may further include a protective overcoat layer positioned above the surface of the substrate, and a sphere-shaped magnetic concentrator positioned above the protective overcoat layer and above the horizontal-type Hall sensor. The structure may further include an array of horizontal-type Hall sensors positioned within the substrate and below the surface of the substrate, and an array of sphere-shaped magnetic concentrators positioned above the protective overcoat layer, wherein the sphere-shaped magnetic concentrators are respectively positioned above the horizontal-type Hall sensors.

The structure may further include a protective overcoat layer positioned above the surface of the substrate, and a patterned magnetic concentrator positioned above the surface of the substrate and below the protective overcoat layer. The structure may further include an array of horizontal-type Hall sensors positioned within the substrate and below the surface of the substrate, and an array of embedded magnetic concentrators positioned within the substrate, and wherein the embedded magnetic concentrators are respectively positioned below the horizontal-type Hall sensors.

In another example, a method of forming a structure includes forming a substrate including a surface, positioning a horizontal-type Hall sensor within the substrate and below the surface of the substrate, and forming an embedded magnetic concentrator within the substrate and below the horizontal-type Hall sensor. The embedded magnetic concentrator may include a shape selected from the group consisting of rod, pyramid, cylindrical, and combinations thereof. The method may further include positioning an array of horizontal-type Hall sensors within the substrate and below the surface of the substrate, and forming an array of embedded magnetic concentrators within the substrate, wherein the step of forming the array of embedded magnetic concentrators within the substrate includes respectively positioning the embedded magnetic concentrators below the horizontal-type Hall sensors.

The method may further include forming a protective overcoat layer above the surface of the substrate, and placing a sphere-shaped magnetic concentrator above the protective overcoat layer and above the horizontal-type Hall sensor. The method may further include positioning an array of horizontal-type Hall sensors within the substrate and below the surface of the substrate, and placing an array of sphere-shaped magnetic concentrators above the protective overcoat layer, wherein the step of placing the array of sphere-shaped magnetic concentrators above the protective overcoat layer includes respectively positioning the sphere-shaped magnetic concentrators above the horizontal-type Hall sensors.

The method may further include forming a protective overcoat layer above the surface of the substrate, and forming a patterned magnetic concentrator above the surface of the substrate and below the protective overcoat layer. The method may further include positioning an array of horizontal-type Hall sensors within the substrate and below the surface of the substrate, and forming an array of embedded magnetic concentrators within the substrate, wherein the step of forming the array of embedded magnetic concentrators within the substrate includes respectively positioning the embedded magnetic concentrators below the horizontal-type Hall sensors.

Any particular magnetic concentrator (i.e., their type and positioning) described in the examples above may be used in combination with any or all of the other-mentioned types (and positioning) of magnetic concentrators in the examples above. For example, the patterned magnetic concentrator 230 may be used in combination with the pyramid-shaped embedded magnetic concentrator 532.

In this description, the term “couple” or “couples” means either an indirect or direct wired or wireless connection. Thus, if a first device couples to a second device, that connection may be through a direct connection or through an indirect connection via other devices and connections. The recitation “based on” means “based at least in part on.” Therefore, if X is based on Y, X may be a function of Y and any number of other factors.

Modifications are possible in the described embodiments, and other embodiments are possible, within the scope of the claims.

What is claimed is:

1. A structure, comprising:
a substrate comprising a surface;
a horizontal-type Hall sensor positioned within the substrate and below the surface of the substrate;
a protective overcoat layer positioned above the surface of the substrate; and
a sphere-shaped magnetic concentrator positioned above the protective overcoat layer.

2. The structure of claim 1, wherein the sphere-shaped magnetic concentrator is positioned above the horizontal-type Hall sensor.

3. The structure of claim 1, wherein the structure further comprises an array of horizontal-type Hall sensors positioned within the substrate and below the surface of the substrate, and an array of sphere-shaped magnetic concentrators positioned above the protective overcoat layer.

4. The structure of claim 3, wherein the sphere-shaped magnetic concentrators are respectively positioned above the horizontal-type Hall sensors.

5. A structure, comprising:
a substrate comprising a surface;
a horizontal-type Hall sensor positioned within the substrate and below the surface of the substrate; and
an embedded magnetic concentrator positioned within the substrate and below the horizontal-type Hall sensor.

6. The structure of claim 5, wherein the embedded magnetic concentrator comprises a shape selected from the group consisting of rod, pyramid, cylindrical, and combinations thereof.

7. The structure of claim 5, wherein the structure further comprises an array of horizontal-type Hall sensors positioned within the substrate and below the surface of the substrate, and an array of embedded magnetic concentrators positioned within the substrate, and wherein the embedded magnetic concentrators are respectively positioned below the horizontal-type Hall sensors.

8. The structure of claim 5, wherein the structure further comprises:
a protective overcoat layer positioned above the surface of the substrate; and
a sphere-shaped magnetic concentrator positioned above the protective overcoat layer and above the horizontal-type Hall sensor.

9. The structure of claim 8, wherein the structure further comprises an array of horizontal-type Hall sensors positioned within the substrate and below the surface of the substrate, and an array of sphere-shaped magnetic concentrators positioned above the protective overcoat layer, and wherein the sphere-shaped magnetic concentrators are respectively positioned above the horizontal-type Hall sensors.

10. The structure of claim 5, wherein the structure further comprises:
a protective overcoat layer positioned above the surface of the substrate; and
a patterned magnetic concentrator positioned above the surface of the substrate and below the protective overcoat layer.

11. The structure of claim 10, wherein the structure further comprises an array of horizontal-type Hall sensors positioned within the substrate and below the surface of the substrate, and an array of embedded magnetic concentrators positioned within the substrate, and wherein the embedded magnetic concentrators are respectively positioned below the horizontal-type Hall sensors.

12. A method of forming a structure, the method comprising:
forming a substrate comprising a surface;
positioning a horizontal-type Hall sensor within the substrate and below the surface of the substrate;
forming a protective overcoat layer above the surface of the substrate; and
placing a sphere-shaped magnetic concentrator above the protective overcoat layer.

13. The method of claim 12, wherein the step of placing comprises positioning the sphere-shaped magnetic concentrator above the horizontal-type Hall sensor.

14. The method of claim 12 further comprising positioning an array of horizontal-type Hall sensors within the substrate and below the surface of the substrate, and placing an array of sphere-shaped magnetic concentrators above the protective overcoat layer.

15. The method of claim 14, wherein the step of placing the array of sphere-shaped magnetic concentrators above the protective overcoat layer comprises respectively positioning the sphere-shaped magnetic concentrators above the horizontal-type Hall sensors.

16. A method of forming a structure, the method comprising:
forming a substrate comprising a surface;
positioning a horizontal-type Hall sensor within the substrate and below the surface of the substrate; and
forming an embedded magnetic concentrator within the substrate and below the horizontal-type Hall sensor.

17. The method of claim 16, wherein the embedded magnetic concentrator comprises a shape selected from the group consisting of rod, pyramid, cylindrical, and combinations thereof.

18. The method of claim 16 further comprising positioning an array of horizontal-type Hall sensors within the substrate and below the surface of the substrate, and forming an array of embedded magnetic concentrators within the substrate, wherein the step of forming the array of embedded magnetic concentrators within the substrate comprises respectively positioning the embedded magnetic concentrators below the horizontal-type Hall sensors.

19. The method of claim 16 further comprising:
forming a protective overcoat layer above the surface of the substrate; and
placing a sphere-shaped magnetic concentrator above the protective overcoat layer and above the horizontal-type Hall sensor.

20. The method of claim 19 further comprising positioning an array of horizontal-type Hall sensors within the substrate and below the surface of the substrate, and placing an array of sphere-shaped magnetic concentrators above the protective overcoat layer, wherein the step of placing the array of sphere-shaped magnetic concentrators above the protective overcoat layer comprises respectively positioning the sphere-shaped magnetic concentrators above the horizontal-type Hall sensors.

21. The method of claim 16 further comprising:
forming a protective overcoat layer above the surface of the substrate; and
forming a patterned magnetic concentrator above the surface of the substrate and below the protective overcoat layer.

22. The method of claim 21 further comprising positioning an array of horizontal-type Hall sensors within the substrate and below the surface of the substrate, and forming an array of embedded magnetic concentrators within the substrate, wherein the step of forming the array of embedded magnetic concentrators within the substrate comprises respectively positioning the embedded magnetic concentrators below the horizontal-type Hall sensors.
